(19) United States
(12) Patent Application Publication
(10) Pub. No.: US 2026/0362674 A1
(43) Pub. Date: Nov. 12, 2026

(54) SEMICONDUCTOR DEVICE INCLUDING CAPACITOR

(71) Applicant: Samsung Electronics Co., Ltd., Suwon-si (KR)

(72) Inventors: Jung Min PARK, Suwon-si (KR); Jun Goo KANG, Suwon-si (KR); Beom-Jong KIM, Suwon-si (KR); Hyung Suk JUNG, Suwon-si (KR)

(73) Assignee: Samsung Electronics Co., Ltd., Suwon-si (KR)

(21) Appl. No.: 19/457,354

(22) Filed: Jan. 23, 2026

(30) Foreign Application Priority Data
May 7, 2025 (KR) 10-2025-0058861

(51) Int. Cl. H10B 12/00

(52) U.S. Cl. CPC H10B 12/315; H10B 12/318; H10B 12/34; H10B 12/482; H10B 12/485; H10B 12/488; H10B 12/033

(57) ABSTRACT

A semiconductor device includes a lower electrode extending in a first direction and that includes an electrode film and an insertion film including different materials; first and second supporter patterns on a side wall of the lower electrode, the first and second supporter patterns spaced apart in the first direction; a capacitor dielectric film on the lower electrode and the first and second supporter patterns; and an upper electrode on the capacitor dielectric film. The electrode film includes stacked first, second and third electrode films. The insertion film includes first and second insertion films, the first insertion film between the first and second electrode films, and the second insertion film between the second and third electrode films. The first insertion film is below the first supporter pattern in the first direction, and the second insertion film is between the first and second supporter patterns in the first direction.

### CROSS-REFERENCE TO RELATED APPLICATION

This application claims priority from Korean Patent Application No. 10-2025-0058861 filed on May 7, 2025, in the Korean Intellectual Property Office, and all the benefits accruing therefrom under 35 U.S.C. 119, the contents of which in its entirety are herein incorporated by reference.

### BACKGROUND

The present disclosure relates to semiconductor devices, and to semiconductor devices that use a capacitor as a data storage element, and methods for fabricating the same.

In recent years, as semiconductor elements have become larger in capacity and more highly integrated, design rules have also continually decreased. Such tendencies have also been focused with respect to DRAMs, which are a type of memory semiconductor elements. In order for a DRAM device to operate, a capacitance (electrostatic capacity) of a certain level or higher is desired for each cell.

In order to increase the capacitance, a method of utilizing a dielectric film with a high dielectric constant for the capacitor, a method of increasing a contact area between a lower electrode of the capacitor and the dielectric film, and a method of increasing an aspect ratio of the lower electrode of the capacitor have been researched. There is a desire for a method for limiting and/or preventing the lower electrode of the capacitor from tilting or bending, when increasing the aspect ratio of the lower electrode of the capacitor.

### SUMMARY

Some example embodiments of the present disclosure provide semiconductor devices that may have improved electrical characteristics and/or reliability.

However, some example embodiments of the present disclosure are not restricted as set forth herein. The above and other aspects of the present disclosure will become more apparent to one of ordinary skill in the art to which the present disclosure pertains by referencing the detailed description of the present disclosure given below.

Some example embodiments provide a semiconductor device that includes a lower electrode extending in a first direction, the lower electrode including an electrode film and an insertion film, the electrode film and the insertion film including different materials from each other; a first supporter pattern on a side wall of the lower electrode; a second supporter pattern on the side wall of the lower electrode, the second supporter pattern being spaced apart from the first supporter pattern in the first direction; a capacitor dielectric film on the lower electrode, the first supporter pattern, and the second supporter pattern; and an upper electrode on the capacitor dielectric film. The electrode film includes a first electrode film, a second electrode film on the first electrode film, and a third electrode film on the second electrode film. The insertion film includes a first insertion film and a second insertion film, the first insertion film between the first electrode film and the second electrode film, and the second insertion film between the second electrode film and the third electrode film. The first insertion film is below the first supporter pattern in the first direction, and the second insertion film is between the first supporter pattern and the second supporter pattern in the first direction.
Some example embodiments further provide a semiconductor device that includes a lower electrode extending in a first direction, the lower electrode including a first electrode film, a second electrode film spaced apart from the first electrode film in the first direction, and a first insertion film between the first electrode film and the second electrode film; a first supporter pattern on one of a side wall of the first electrode film and a side wall of the second electrode film; a capacitor dielectric film on the lower electrode and the first supporter pattern; and an upper electrode on the capacitor dielectric film. A material of the first insertion film includes a material different than a material of the first electrode film and a material of the second electrode film.
Some example embodiments still further provide a semiconductor device that includes a substrate including an active region defined by an element isolation film, the active region extending in a first direction, and the active region including a first portion and a second portion defined on both sides of the first portion; a word line extending in a second direction different than the first direction, the word line extending in the substrate and the element isolation film, and the word line crossing between the first portion of the active region and the second portion of the active region; a bit line contact electrically connected to the first portion of the active region; a bit line on the bit line contact, the bit line being electrically connected to the bit line contact, and the bit line extending in a third direction different than the first direction and the second direction; a landing pad electrically connected to the second portion of the active region; a capacitor structure electrically connected to the landing pad; and a first supporter pattern on the capacitor structure. The capacitor structure includes a lower electrode electrically connected to the landing pad, the lower electrode extending in a fourth direction; a capacitor dielectric film on the lower electrode and the first supporter pattern; and an upper electrode on the capacitor dielectric film. The lower electrode includes a first electrode film, a first insertion film, and a second electrode film stacked in sequence in the fourth direction. The first supporter pattern overlaps one of the first electrode film and the second electrode film in the first direction, the second direction and the third direction, and does not overlap the first insertion film in the first direction, the second direction and the third direction.

### BRIEF DESCRIPTION OF THE DRAWINGS

The above and other aspects and features of the present disclosure will become more apparent in view of the following detailed description of some example embodiments with reference to the attached drawings, in which:

FIG. 1 is a schematic layout of a semiconductor device according to some example embodiments;

FIG. 2 is a cross-sectional view taken along A-A of FIG. 1;

FIG. 3 is a cross-sectional view taken along B-B of FIG. 1;

FIG. 4 is a diagram for explaining the semiconductor device according to some example embodiments;

FIG. 5 is a diagram for explaining the semiconductor device according to some example embodiments;

FIGS. 6 and 7 are diagrams for explaining the semiconductor device according to some example embodiments;

FIG. 8 is a diagram for explaining the semiconductor device according to some example embodiments;

FIG. 9 is a layout diagram for explaining the semiconductor device according to some example embodiments;

FIG. 10 is a perspective view for explaining the semiconductor device of FIG. 9;

FIG. 11 is a cross-sectional view taken along D-D and E-E of FIG. 9;

FIG. 12 is a diagram for explaining the semiconductor device according to some example embodiments;

FIG. 13 is a layout diagram for explaining the semiconductor device according to some example embodiments;

FIG. 14 is a perspective view for explaining the semiconductor device of FIG. 13;

FIGS. 15 to 22 are intermediate stage diagrams for explaining a method for fabricating a semiconductor device according to some example embodiments; and

FIGS. 23 to 25 are intermediate stage diagrams for explaining the method for fabricating the semiconductor device according to some example embodiments.

### DETAILED DESCRIPTION

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure.
When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.
Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

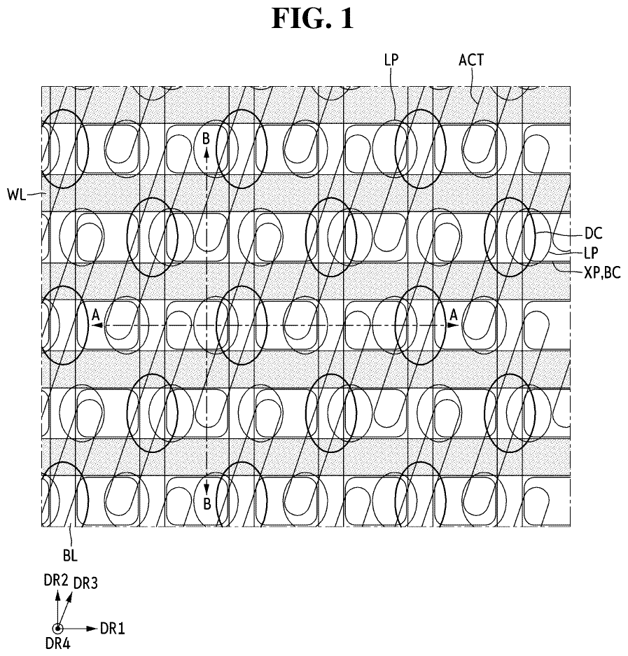

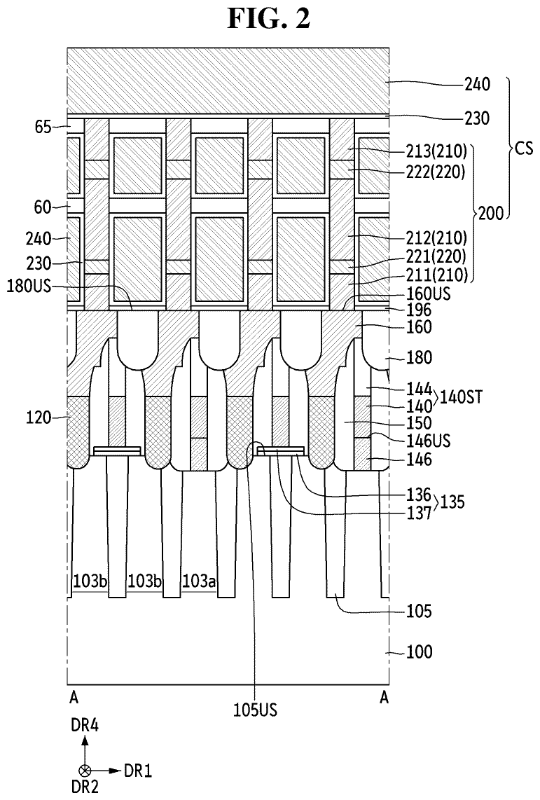

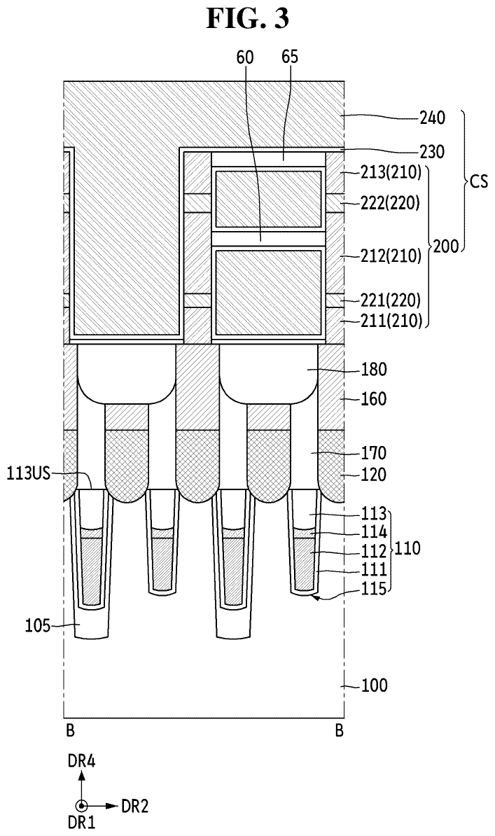

FIG. 1 is a schematic layout of a semiconductor device according to some example embodiments. FIG. 2 is a cross-sectional view taken along A-A of FIG. 1. FIG. 3 is a cross-sectional view taken along B-B of FIG. 1.

In the diagrams relating to the semiconductor device according to some example embodiments, although a dynamic random access memory (DRAM) is shown as an example, some example embodiments are not limited thereto.

Referring to FIGS. 1 to 3, the semiconductor device according to some example embodiments may include a plurality of cell active regions ACT.

The cell active region ACT may be defined by a cell element isolation film 105 formed inside the substrate 100. As the design rule of the semiconductor device decreases, the cell active region ACT may be disposed in the form of a bar of a diagonal line or an oblique line, as shown. For example, the cell active region ACT may extend in a third direction DR3.

A plurality of word lines WL extending in a first direction DR1 across the cell active region ACT may be disposed. The plurality of word lines WL may extend parallel to each other. The word lines WL may be disposed at equal intervals. A width of the word lines WL or an interval between the word lines WL may be determined depending on the design rule.

Each cell active region ACT may be divided into three portions by two word lines WL extending in the first direction DR1. The cell active region ACT may include a storage connecting region 103b and a bit line connecting region 103a. The bit line connecting region 103a may be located at a central portion of the cell active region ACT, and the storage connecting region 103b may be located at an end portion of the cell active region ACT.

For example, the bit line connecting region 103a may be a region connected to the bit line BL, and the storage connecting region 103b may be a region connected to a capacitor structure CS. For example, the bit line connecting region 103a may correspond to a common drain region, and the storage connecting region 103b may correspond to a source region. Each word line WL, and the bit line connecting region 103a and storage connecting region 103b adjacent thereto may form a transistor.

A plurality of bit lines BL extending in a second direction DR2 orthogonal to the word line WL may be disposed on the word line WL. The plurality of bit lines BL may extend parallel to each other. The bit lines BL may be disposed at equal intervals. The width of the bit line BL or the interval between the bit lines BL may be determined depending on the design rule.

The first direction DR1, the second direction DR2, and the third direction DR3 may be aligned with an upper side of the substrate 100 on which the capacitor structure CS is disposed. The second direction DR2 may be orthogonal to the first direction DR1. The third direction DR3 may be a direction between the first direction DR1 and the second direction DR2. A fourth direction DR4 may be orthogonal to the upper side of the substrate 100 on which the capacitor structure CS is disposed. Hereinafter, the upper side, a lower side, an upper portion, and a lower portion are defined on the basis of the fourth direction DR4.

The semiconductor memory device according to some example embodiments may include various contact arrangements formed on the cell active region ACT. The various contact arrangements may include, for example, a direct contact DC, a buried contact BC, a landing pad LP, and the like.

Here, the direct contact DC may refer to a contact that electrically connects the cell active region ACT to the bit line BL. The buried contact BC may be a connecting pad that connects the cell active region ACT to the lower electrode 200 of the capacitor structure CS. The contact area between the buried contact BC and the cell active region ACT may be small due to the placement structure. Therefore, a conductive landing pad LP may be introduced to enlarge the contact area with the cell active region ACT and to enlarge the contact area with the lower electrode 200 of the capacitor structure CS.

In the semiconductor device according to some example embodiments, the landing pad LP may be disposed between the buried contact BC and the lower electrode 200 of the capacitor structure CS. By enlarging the contact area through the introduction of the landing pad LP, the contact resistance between the cell active region ACT and the lower electrode 200 of the capacitor structure CS may decrease.

The direct contact DC may be connected to the bit line connecting region 103a. The buried contact BC may be connected to the storage connecting portion 103b.

As the buried contact BC is disposed at both ends of the cell active region ACT, the landing pad LP may be disposed adjacent to both ends of the cell active region ACT to overlap the buried contact BC. For example, the buried contact BC may be formed to overlap the cell active region ACT and the cell element isolation film 105 between the adjacent word line WL and the adjacent bit line BL.

The word line WL may be formed as a structure buried in the substrate 100. The word line WL may be disposed across the cell active region ACT between the direct contact DC and the buried contact BC. As shown, two word lines WL may be disposed to intersect one cell active region ACT. As the cell active region ACT extends along the third direction DR3, the word line WL may have an angle of less than 90 degrees with the cell active region ACT.

The direct contact DC and the buried contact BC may be disposed symmetrically. Therefore, the direct contact DC and the buried contact BC may be disposed in a straight line along the first direction DR1 and the second direction DR2. On the other hand, unlike the direct contact DC and the buried contact BC, the landing pad LP may be disposed in zigzags in the second direction DR2 in which the bit lines BL extend. Also, the landing pads LP may be disposed to overlap the same side portions of each bit line BL in the first direction DR1 in which the word lines WL extend.

For example, each of the landing pads LP of the first line may overlap the left side of the corresponding bit line BL, and each of the landing pads LP of the second line may overlap the right side of the corresponding bit line BL.

The semiconductor device according to some example embodiments may include a plurality of cell gate structures 110, a plurality of bit line structures 140ST, a plurality of storage contacts 120, a plurality of bit line contacts 146, and a capacitor structure CS.

The substrate 100 may be a silicon substrate or a silicon-on-insulator (SOI). In contrast, the substrate 100 may include, but is not limited to, silicon germanium, silicon germanium-on-insulator (SGOI), indium antimonide, lead telluride, indium arsenide, indium phosphide, gallium arsenide or gallium antimonide.

The cell element isolation film 105 may be formed inside the substrate 100. The cell element isolation film 105 may have a shallow trench isolation (STI) structure having excellent element isolation properties. The cell element isolation film 105 may define a cell active region ACT inside the memory cell region.

The cell active region ACT defined by the cell element isolation film 105 may have a long island shape including a short axis and a long axis as shown in FIG. 1. The cell active region ACT may have an oblique line shape to have an angle of less than 90 degrees with respect to the word line WL formed in the cell element isolation film 105. The cell active region ACT may also have an oblique line shape with an angle of less than 90 degrees with respect to the bit line BL formed on the cell element isolation film 105.

The cell element isolation film 105 may include, but is not limited to, at least one of a silicon oxide film, a silicon nitride film, and a silicon oxynitride film.

Although the cell element isolation film 105 is shown as being formed of a single insulating film, this is only for convenience of explanation, and some example embodiments are not limited thereto. The cell element isolation film 105 may be formed of a single insulating film or a plurality of insulating films, depending on the distance between adjacent cell active regions ACT.

Although an upper side 105US of the cell element isolation film and an upper side of the substrate 100 are shown as being placed on the same plane, this is only for convenience of explanation, and some example embodiments are not limited thereto.

The cell gate structure 110 may be disposed inside the substrate 100 and the cell element isolation film 105. The cell gate structure 110 may be formed across the cell element isolation film 105 and the cell active region ACT defined by the cell element isolation film 105.

The cell gate structure 110 may include a cell gate trench 115, a cell gate insulating film 111, a cell gate electrode 112, a cell gate capping pattern 113, and a cell gate capping conductive film 114.

The cell gate electrode 112 may correspond to the word line WL of FIG. 1. Unlike the shown example, the cell gate structure 110 may not include the cell gate capping conductive film 114.

Although not shown, the cell gate trench 115 may be relatively deep in the cell element isolation film 105 and relatively shallow in the cell active region ACT. A bottom side of the word line WL may be curved. The depth of the cell gate trench 115 in the cell element isolation film 105 may be greater than the depth of the cell gate trench 115 in the cell active region ACT.

The cell gate insulating film 111 may extend along the side wall and bottom side of the cell gate trench 115. The cell gate insulating film 111 may extend along the profile of at least a part of the cell gate trench 115.

The cell gate insulating film 111 may include, for example, at least one of silicon oxide, silicon nitride, silicon oxynitride, or a high dielectric constant material having a higher dielectric constant than silicon oxide. The high dielectric constant material may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate or a combination thereof.

The cell gate electrode 112 may be disposed on the cell gate insulating film 111. The cell gate electrode 112 may fill a part of the cell gate trench 115. The cell gate capping conductive film 114 may extend along an upper side of the cell gate electrode 112.

The cell gate electrode 112 may include at least one of a metal, a conductive metal nitride, a conductive metal carbonitride, a conductive metal carbide, a conductive metal silicide, a doped semiconductor material, a conductive metal oxynitride, and a conductive metal oxide. The cell gate electrode 112 may include, for example, but is not limited to, TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrO, RuO or combinations thereof.

The cell gate capping conductive film 114 may include, but is not limited to, one of polysilicon, polysilicon-germanium, amorphous silicon, or amorphous silicon-germanium.

The cell gate capping pattern 113 may be disposed on the cell gate electrode 112 and the cell gate capping conductive film 114. The cell gate capping pattern 113 may fill the cell gate trench 115 that remains after the cell gate electrode 112 and the cell gate capping conductive film 114 are formed. Although the cell gate insulating film 111 is shown to extend along the side wall of the cell gate capping pattern 113, some example embodiments are not limited thereto.

The cell gate capping pattern 113 may include, for example, but is not limited to, at least one of silicon nitride, silicon oxynitride, silicon oxide, silicon carbonitride or silicon oxycarbonitride.

An upper side 113US of the cell gate capping pattern is shown as being coplanar with the upper side 105US of the cell element isolation film, but is not limited thereto.

Although not shown, an impurity doping region may be formed on at least one side of the cell gate structure 110. The impurity doping region may be a source/drain region of a transistor. The impurity doping region may be formed in the storage connecting region 103b and the bit line connecting region 103a.

When a transistor including each word line WL, and the bit line connecting region 103a and storage connecting region 103b adjacent thereto is an NMOS, the storage connecting region 103b and the bit line connecting region 103a may include doped n-type impurities, for example, at least one of phosphorus (P), arsenic (As), antimony (Sb) or bismuth (Bi). When the transistor including each word line WL and the bit line connecting region 103a and storage connecting region 103b adjacent thereto is a PMOS, the storage connecting region 103b and the bit line connecting region 103a may include doped p-type impurities, for example, at least one of boron (B) or gallium (Ga).

The bit line structure 140ST may include a cell conductive line 140 and a cell line capping film 144. The cell conductive line 140 may be disposed on the substrate 100 and the cell element isolation film 105 in which the cell gate structure 110 is formed. The cell conductive line 140 may intersect the cell element isolation film 105 and the cell active region ACT defined by the cell element isolation film 105. The cell conductive line 140 may be formed to intersect the cell gate structure 110. Here, the cell conductive line 140 may correspond to the bit line BL. For example, the cell conductive line 140 may be the bit line BL of FIG. 1.

The cell conductive line 140 may include, for example, at least one of an impurity-doped semiconductor material, a conductive metal silicide, a conductive metal nitride, a conductive metal oxide, a two-dimensional material (2D material) or a metal. In the semiconductor device according to some example embodiments, the two-dimensional material may be a metallic material and/or a semiconductor material. The 2D material may include a 2D allotrope or a 2D compound, and may include, but is not limited to, at least one of graphene, molybdenum disulfide (MoS₂), molybdenum diselenide (MoSe₂), tungsten diselenide (WSe₂) or tungsten disulfide (WS₂). Since the above-mentioned 2D materials are only listed as an example, the 2D materials that may be included in the semiconductor memory device of the present disclosure are not limited by the above-mentioned materials.

The cell conductive line 140 is shown as being a single film, but this is only for convenience of explanation, and some example embodiments are not limited thereto. Unlike the shown example, the cell conductive line 140 may include a plurality of conductive films in which conductive materials are stacked.

The cell line capping film 144 may be disposed on the cell conductive line 140. The cell line capping film 144 may extend in the second direction DR2 along the upper side of the cell conductive line 140. The cell line capping film 144 may include, for example, at least one of silicon nitride, silicon oxynitride, silicon carbonitride or silicon oxycarbonitride.

In the semiconductor device according to some example embodiments, the cell line capping film 144 may include silicon nitride. Although the cell line capping film 144 is shown as being a single film, some example embodiments are not limited thereto.

The bit line spacers 150 may be disposed on side walls of the cell conductive lines 140 and the cell line capping films 144. The bit line spacers 150 extend long in the second direction DR2.

Although the bit line spacer 150 is shown as being a single film, this is only for convenience of explanation, and some example embodiments are not limited thereto. For example, unlike the shown example, the bit line spacer 150 may have a multi-layer film structure. The bit line spacer 150 may include, for example, but is not limited to, a silicon oxide film, a silicon nitride film, a silicon oxynitride film (SiON), a silicon oxycarbonitride film (SiOCN), air or a combination thereof.

The lower cell insulating film 135 may be disposed on the substrate 100 and the cell element isolation film 105. For example, the lower cell insulating film 135 may be disposed on the substrate 100 and the upper side 105US of the cell element isolation film on which the bit line contact 146 and the storage contact 120 are not formed. The lower cell insulating film 135 may be disposed between the substrate 100 and the cell conductive line 140, and between the cell element isolation film 105 and the cell conductive line 140.

Although the lower cell insulating film 135 may be a single film, as shown, the lower cell insulating film 135 may be a multi-layer film including a first lower cell insulating film 136 and a second lower cell insulating film 137. For example, the first lower cell insulating film 136 may include silicon oxide, and the second lower cell insulating film 137 may include silicon nitride, but some example embodiments are not limited thereto. Unlike the shown example, the lower cell insulating film 135 may be, but is not limited to, a triple film including a silicon oxide film, a silicon nitride film, and a silicon oxide film.

The bit line contact 146 may be disposed between the cell conductive line 140 and the substrate 100. The cell conductive line 140 may be disposed on the bit line contact 146.

The bit line contact 146 may be disposed between the bit line connecting region 103a of the cell active region ACT and the cell conductive line 140. The bit line contact 146 may be connected to the bit line connecting region 103a.

The bit line contact 146 may include an upper side 146US connected to the cell conductive line 140. Although the width of the bit line contact 146 in the first direction DR1 is shown to be constant as it goes away from the upper side 146US of the bit line contact, this is only for convenience of explanation, and some example embodiments are not limited thereto.

The bit line contact 146 may electrically connect the cell conductive line 140 and the substrate 100. Here, the bit line contact 146 may correspond to a direct contact DC. The bit line contact 146 may include, for example, at least one of an impurity-doped semiconductor material, a conductive metal silicide, a conductive metal nitride, a conductive metal oxide, or a metal.

In the portion of the cell conductive line 140 in which the bit line contact 146 is formed, a bit line spacer 150 may be disposed on the substrate 100 and the cell element isolation film 105. The bit line spacer 150 may be disposed on the side walls of the cell conductive line 140, the cell line capping film 144, and the bit line contact 146.

In the remaining portion of the cell conductive line 140 in which the bit line contact 146 is not formed, the bit line spacer 150 may be disposed on the lower cell insulating film 135. The bit line spacer 150 may be disposed on the side walls of the cell conductive line 140 and the cell line capping film 144.

A fence pattern 170 may be disposed on the substrate 100 and the cell element isolation film 105. The fence pattern 170 may be formed to overlap the cell gate structure 110 formed inside the substrate 100 and the cell element isolation film 105.

The fence pattern 170 may be disposed between the bit line structures 140ST extending in the second direction DR2. The fence pattern 170 may include, for example, at least one of silicon oxide, silicon nitride or silicon oxynitride.

The storage contact 120 may be disposed between the cell conductive lines 140 adjacent to each other in the first direction DR1. The storage contact 120 may be disposed on both sides of the cell conductive line 140. For example, the storage contact 120 may be disposed between the bit line structures 140ST. The storage contact 120 may be disposed between the fence patterns 170 adjacent to each other in the second direction DR2.

The storage contact 120 may overlap the substrate 100 and the cell element isolation film 105 between adjacent cell conductive lines 140. The storage contact 120 may be connected to the cell active region ACT. For example, the storage contact 120 may be connected to the storage connecting portion 103b. Here, the storage contact 120 may correspond to the buried contact BC of FIG. 1.

The storage contact 120 may include, for example, at least one of an impurity-doped semiconductor material, a conductive metal silicide, a conductive metal nitride, a conductive metal carbide, a conductive metal carbonitride, a conductive metal oxide or a metal.

The storage pad 160 may be disposed on the storage contact 120. The storage pad 160 may be electrically connected to the storage contact 120. The storage pad 160 may be connected to the storage connecting portion 103b of the cell active region ACT. Here, the storage pad 160 may correspond to the landing pad LP.

The storage pad 160 may overlap a part of the upper side of the bit line structure 140ST. The storage pad 160 may include, for example, at least one of an impurity-doped semiconductor material, a conductive metal silicide, a conductive metal nitride, a conductive metal carbide, a conductive metal oxide or a metal.

A pad isolation insulating film 180 may be disposed on the storage pad 160 and the bit line structure 140ST. For example, the pad isolation insulating film 180 may be disposed on the cell line capping film 144. The pad isolation insulating film 180 may define the storage pad 160 that forms a plurality of isolation regions.

The pad isolation insulating film 180 does not cover the upper side 160US of the storage pad. The pad isolation insulating film 180 may fill the pad isolation recess. The pad isolation recess may separate adjacent storage pads 160. For example, the upper side 160US of the storage pad may be disposed on the same plane as the upper side 180US of the pad isolation insulating film, but is not limited thereto.

The pad isolation insulating film 180 includes an insulating material, and may electrically isolate the plurality of storage pads 160 from each other. For example, the pad isolation insulating film 180 may include, for example, but is not limited to, at least one of silicon oxide, silicon nitride, silicon oxynitride, silicon oxycarbonitride, or silicon carbonitride.

A first etch stop layer 196 may be disposed on the upper side 160US of the storage pad and on the upper side 180US of the pad isolation insulating film. The first etch stop layer 196 may include, for example, at least one of silicon nitride, silicon carbonitride, silicon oxycarbonitride, silicon oxycarbide or silicon boron nitride.

The capacitor structure CS may be disposed on the storage pad 160. The capacitor structure CS may be electrically connected to the storage pad 160. A part of the capacitor structure CS may be disposed inside the first etch stop layer 196.

The capacitor structure CS may include a lower electrode 200, a capacitor dielectric film 230, and an upper electrode 240.

The lower electrode 200 may be electrically connected to the storage pad 160. For example, the lower electrode 200 may be in contact with at least a part of the upper side 160US of the storage pad exposed by the first etch stop layer 196. The lower electrode 200 may extend in a fourth direction DR4. The lower electrode 200 may be in the form of a pillar extending in the fourth direction DR4 from the upper side 160US of the storage pad 160.

At least one or more supporter patterns 60 and 65 may be disposed on the first etch stop layer 196. The at least one or more supporter patterns 60 and 65 may support the lower electrode 200.

For example, a plurality of supporter patterns 60 and 65 may be disposed on the first etch stop layer 196. The plurality of supporter patterns 60 and 65 may include a first supporter pattern 60 and a second supporter pattern 65 that are sequentially disposed on the first etch stop layer 196. The first supporter pattern 60 and the second supporter pattern 65 may be spaced apart from the first etch stop layer 196 in the fourth direction DR4. The first supporter pattern 60 and the second supporter pattern 65 may be spaced apart from each other in the fourth direction DR4. In the fourth direction DR4, a thickness of the first supporter pattern 60 may be equal to or different from a thickness of the second supporter pattern 65.

Each of the first supporter pattern 60 and the second supporter pattern 65 may be in contact with a part of the lower electrode 200. Each of the first supporter pattern 60 and the second supporter pattern 65 may be in contact with a side wall of the lower electrode 200. Although the number of supporter patterns that are in contact with the lower electrode 200 is shown as two, this is only for convenience of explanation, and some example embodiments are not limited thereto.

Each of the first supporter pattern 60 and the second supporter pattern 65 may include at least one of, for example, silicon nitride, silicon carbonitride, silicon boron nitride, silicon oxycarbide, silicon oxynitride or silicon oxycarbonitride.

The lower electrode 200 includes an electrode film 210 and an insertion film 220. At least one insertion film 220 may be disposed at least one of a location between adjacent storage pad 160 and supporter pattern 60, and a location between adjacent supporter patterns 60 and 65.

In some example embodiments, at least one insertion film 220 may be disposed between the adjacent storage pad 160 and supporter pattern 60, and between adjacent supporter patterns 60 and 65, respectively.

In some example embodiments, the number of insertion films 220 disposed between the adjacent storage pad 160 and first supporter pattern 60 may be the same as the number of insertion films 220 disposed between adjacent first and second supporter patterns 60 and 65.

For example, the electrode film 210 may include a first electrode film 211, a second electrode film 212, and a third electrode film 213, and the insertion film 220 may include a first insertion film 221 and a second insertion film 222.

The second electrode film 212 may be disposed on the first electrode film 211. The second electrode film 212 may be spaced apart from the first electrode film 211 in the fourth direction DR4. The third electrode film 213 may be disposed on the second electrode film 212. The third electrode film 213 may be spaced apart from the second electrode film 212 in the fourth direction DR4. The first insertion film 221 may be disposed between the first electrode film 211 and the second electrode film 212. The second insertion film 222 may be disposed between the second electrode film 212 and the third electrode film 213. The first electrode film 211, the first insertion film 221, the second electrode film 212, the second insertion film 222, and the third electrode film 213 may be sequentially stacked along the fourth direction DR4.

The first insertion film 221 may be disposed between the adjacent storage pad 160 and first supporter pattern 60. The second insertion film 222 may be disposed between the adjacent first supporter pattern 60 and second supporter pattern 65.

The first supporter pattern 60 may be disposed on the second electrode film 212. The first supporter pattern 60 may be disposed on the side wall of the second electrode film 212. The first supporter pattern 60 may overlap the second electrode film 212 in a direction aligned with the upper side of the substrate 100 (e.g., the first direction DR1 to the third direction DR3). The first supporter pattern 60 may be in contact with the second electrode film 212. The first supporter pattern 60 may be in contact with the side wall of the second electrode film 212.

The supporter patterns 60 except for the supporter pattern 65 disposed at the top may not be in contact with the insertion film 220. The supporter patterns 60 except for the supporter pattern 65 disposed at the top may not overlap the insertion film 220 in a direction aligned with the upper side of the substrate 100 (e.g., the first direction DR1 to the third direction DR3). For example, the first supporter pattern 60 may not be in contact with the first insertion film 221. The first supporter pattern 60 may not overlap the first insertion film 221 in the first direction DR1 to the third direction DR3.

In some example embodiments, the supporter pattern 65 disposed at the top may be disposed on the electrode film 210 disposed at the top. The supporter pattern 65 disposed at the top may be in contact with the electrode film 210 disposed at the top. The supporter pattern 65 disposed at the top may overlap the electrode film 210 disposed at the top in a direction aligned with the upper side of the substrate 100 (e.g., the first direction DR1 to the third direction DR3).

For example, the second supporter pattern 65 may be disposed on the third electrode film 213. The second supporter pattern 65 may be disposed on the side wall of the third electrode film 213. The second supporter pattern 65 may overlap the third electrode film 213 in the first direction DR1 to the third direction DR3. The second supporter pattern 65 may be in contact with the third electrode film 213. The second supporter pattern 65 may be in contact with the side wall of the third electrode film 213.

Each of the electrode film 210 and the insertion film 220 may include a conductive material. Each of the electrode film 210 and the insertion film 220 may include, but are not limited to, a conductive metal oxide (e.g., rhenium oxide, iridium oxide, tantalum oxide, niobium oxide, molybdenum oxide, tungsten oxide, vanadium oxide, chromium oxide, indium oxide, etc.), a conductive metal nitride (e.g., titanium nitride, molybdenum nitride, vanadium nitride, chromium nitride, hafnium nitride, zirconium nitride, tungsten nitride, tantalum nitride, etc.), and a metal (e.g., platinum, iridium, tungsten, ruthenium, etc.). In the semiconductor memory device according to some example embodiments, the electrode film 210 may include titanium nitride (TiN).

The insertion film 220 may include a material different from that of the electrode film 210. The thermal expansion coefficient of the insertion film 220 may be different from that of the electrode film 210. For example, the thermal expansion coefficient of the insertion film 220 may have a difference of about 30% from that of the electrode film 210.

The first insertion film 221 and the second insertion film 222 include a material different from the first electrode film 211, the second electrode film 212, and the third electrode film 213. Each of the first electrode film 211, the second electrode film 212, and the third electrode film 213 may include any one of the conductive materials described above, and the first insertion film 221 and the second insertion film 222 may include materials different from the first electrode film 211, the second electrode film 212, and the third electrode film 213 among the conductive materials described above. The thermal expansion coefficients of the first insertion film 221 and the second insertion film 222 may be different from thermal expansion coefficients of the first electrode film 211, the second electrode film 212, and the third electrode film 213. For example, the thermal expansion coefficients of the first insertion film 221 and the second insertion film 222 may differ from the thermal expansion coefficients of the first electrode film 211, the second electrode film 212, and the third electrode film 213 by about 30%.

In some example embodiments, the first insertion film 221 may include the same material as the second insertion film 222. In some example embodiments, the first insertion film 221 may include a different material from the second insertion film 222.

In some example embodiments, the thickness of the first insertion film 221 may be the same as the thickness of the second insertion film 222 in the fourth direction DR4. In some example embodiments, the thickness of the first insertion film 221 may be different from the thickness of the second insertion film 222 in the fourth direction DR4.

The capacitor dielectric film 230 may be disposed on the lower electrode 200, the first supporter pattern 60, and the second supporter pattern 65. The capacitor dielectric film 230 may extend along the side walls and upper side of the lower electrode 200. The capacitor dielectric film 230 may extend along the upper side and the lower side of the first supporter pattern 60. The capacitor dielectric film 230 may extend along the upper side and the lower side of the second supporter pattern 65. The capacitor dielectric film 230 may extend along the upper side of the first etch stop layer 196.

For example, the capacitor dielectric film 230 may include, but is not limited to, at least one of silicon oxide, silicon nitride, silicon oxynitride, hafnium oxide, hafnium silicon oxide, hafnium zirconium oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, lead zirconium titanium oxide, yttrium oxide, aluminum oxide, lead scandium tantalum oxide, lead zinc niobate, and combinations thereof.

As an example, the capacitor dielectric film 230 may include a stacked film structure in which zirconium oxide, aluminum oxide, and zirconium oxide are sequentially stacked. As another example, the capacitor dielectric film 230 may include a dielectric film containing hafnium (Hf). The above-mentioned materials of the capacitor dielectric film 230 are merely examples, and some example embodiments of the present disclosure are not limited thereto.

The capacitor dielectric film 230 may include at least one of a ferroelectric material, an antiferroelectric material, and a paraelectric material. For example, the capacitor dielectric film 230 may include one of the ferroelectric material, the antiferroelectric material, the paraelectric material, a combination of the ferroelectric and antiferroelectric materials, a combination of the ferroelectric and paraelectric materials, a combination of paraelectric and antiferroelectric materials, and a combination of the ferroelectric material, the antiferroelectric material and the paraelectric material.

The upper electrode 240 may be disposed on the capacitor dielectric film 230. The upper electrode 240 may fill between the lower electrodes 200 adjacent to each other in the first direction DR1 and between the lower electrodes 200 adjacent to each other in the second direction DR2. The upper electrode 240 may fill between the first etch stop layer 196 and the first supporter pattern 60, and between the first supporter pattern 60 and the second supporter pattern 65. Although the thickness of the upper electrode 240 between the first etch stop layer 196 and the first supporter pattern 60 is shown as being thicker than the thickness of the upper electrode 240 between the first supporter pattern 60 and the second supporter pattern 65, some example embodiments are not limited thereto.

The upper electrode 240 may include, for example, but is not limited to, a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide).

Unlike the shown example, in the semiconductor device according to some example embodiments, the bit line BL may extend in the fourth direction DR4 on the substrate 100. The active layers may be connected to the bit line BL, extend in the first direction DR1 from the bit line BL, and be spaced apart in the fourth direction DR4. The word line WL may intersect the active layer and extend in the second direction DR2. The capacitor structure CS may be connected to the active layer. The lower electrode 200 of the capacitor structure CS may be connected to the active layer and extend in the first direction DR1.

In the semiconductor device according to some example embodiments, the lower electrode 200 of the capacitor structure CS may include an electrode film 210 and an insertion film 220 including different materials from each other, and at least one insertion film 220 may be disposed in at least one of the positions between the adjacent storage pad 160 and supporter pattern 60, and between the adjacent supporter patterns 60 and 65. Accordingly, since the length of the electrode film 210 exposed by the supporter patterns 60 and 65 decreases, the stress induced in the lower electrode 200 may be alleviated. Therefore, the warping of the lower electrode 200 may be limited and/or prevented and/or improved.

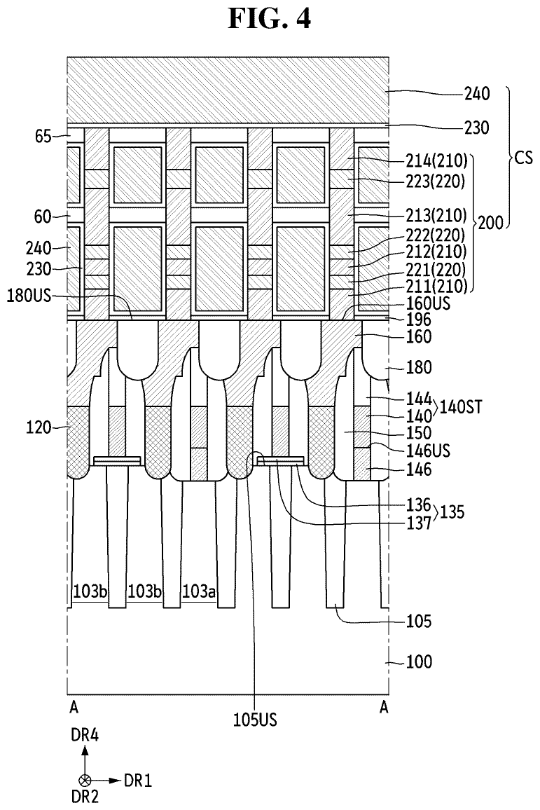

FIG. 4 is a diagram for explaining a semiconductor device according to some example embodiments. For convenience of explanation, differences from the contents explained using FIGS. 1 to 3 will be mainly explained.

Referring to FIG. 4, in the semiconductor device according to some example embodiments, the number of insertion films 220 disposed between the adjacent storage pad 160 and first supporter pattern 60 may be different from the number of insertion films 220 disposed between the adjacent first and second supporter patterns 60 and 65.

For example, the electrode film 210 may include a first electrode film 211, a second electrode film 212, a third electrode film 213, and a fourth electrode film 214, and the insertion film 220 may include a first insertion film 221, a second insertion film 222, and a third insertion film 223. The fourth electrode film 214 may be disposed on the third electrode film 213. The third insertion film 223 may be disposed between the third electrode film 213 and the fourth electrode film 214. The first electrode film 211, the first insertion film 221, the second electrode film 212, the second insertion film 222, the third electrode film 213, the third insertion film 223, and the fourth electrode film 214 may be sequentially stacked along the fourth direction DR4.

The first supporter pattern 60 may be in contact with the third electrode film 213. The second supporter pattern 65 may be in contact with the fourth electrode film 214. The first and second insertion films 221 and 222 may be disposed between the adjacent storage pad 160 and first supporter pattern 60, and the third insertion film 223 may be disposed between adjacent first and second supporter patterns 60 and 65.

In some example embodiments, the plurality of insertion films 220 disposed between adjacent storage pad 160 and first supporter pattern 60 and/or the plurality of insertion films 220 disposed between adjacent first and second supporter patterns 60 and 65 may include the same material as each other or different materials from each other. For example, the first insertion film 221 may include the same material as the second insertion film 222. For example, the first insertion film 221 may include a different material from the second insertion film 222.

In some example embodiments, the plurality of insertion films 220 disposed between adjacent storage pad 160 and first supporter pattern 60 and/or the plurality of insertion films 220 disposed between adjacent first and second supporter patterns 60 and 65 may have the same thickness or different thicknesses in the fourth direction DR4. For example, the thickness of the first insertion film 221 may be the same as the thickness of the second insertion film 222 in the fourth direction DR4. For example, the thickness of the first insertion film 221 may be different from the thickness of the second insertion film 222 in the fourth direction DR4.

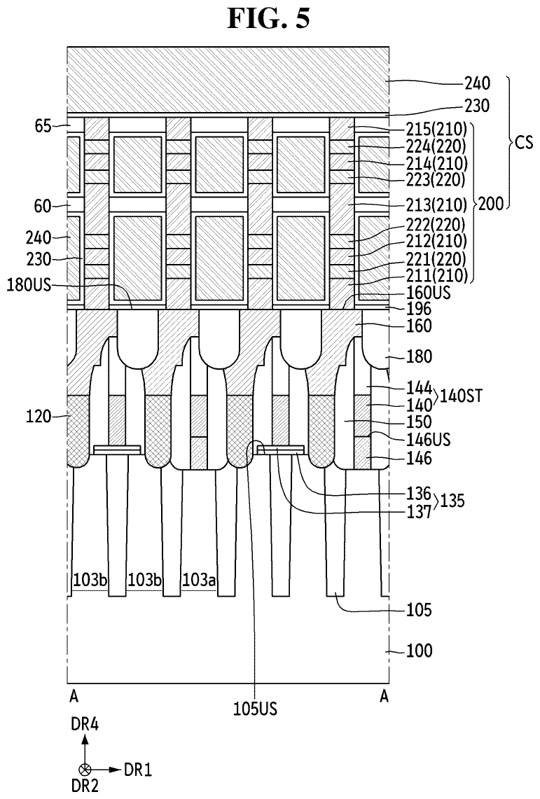

FIG. 5 is a diagram for explaining a semiconductor device according to some example embodiments. For convenience of explanation, differences from the contents explained using FIGS. 1 to 4 will be mainly explained.

Referring to FIG. 5, in the semiconductor device according to some example embodiments, the plurality of insertion films 220 may be disposed between adjacent storage pad 160 and supporter pattern 60 and between adjacent supporter patterns 60 and 65, respectively.

For example, the electrode film 210 may include a first electrode film 211, a second electrode film 212, a third electrode film 213, a fourth electrode film 214, and a fifth electrode film 215. The insertion film 220 may include a first insertion film 221, a second insertion film 222, a third insertion film 223, and a fourth insertion film 224. The fourth electrode film 214 may be disposed on the third electrode film 213. The fifth electrode film 215 may be disposed on the fourth electrode film 214. The fourth insertion film 224 may be disposed between the fourth electrode film 214 and the fifth electrode film 215. The first electrode film 211, the first insertion film 221, the second electrode film 212, the second insertion film 222, the third electrode film 213, the third insertion film 223, the fourth electrode film 214, the fourth insertion film 224, and the fifth electrode film 215 may be sequentially stacked along the fourth direction DR4.

The second supporter pattern 65 may be in contact with the fifth electrode film 215. The first and second insertion films 221 and 222 may be disposed between the adjacent storage pad 160 and the first supporter pattern 60, and the third and fourth insertion films 223 and 224 may be disposed between the adjacent first and second supporter patterns 60 and 65.

For example, the third insertion film 223 may include the same material as the fourth insertion film 224. For example, the third insertion film 223 may include a different material from the fourth insertion film 224. For example, the thickness of the third insertion film 223 may be the same as the thickness of the fourth insertion film 224 in the fourth direction DR4. For example, the thickness of the third insertion film 223 may be different from the thickness of the fourth insertion film 224 in the fourth direction DR4.

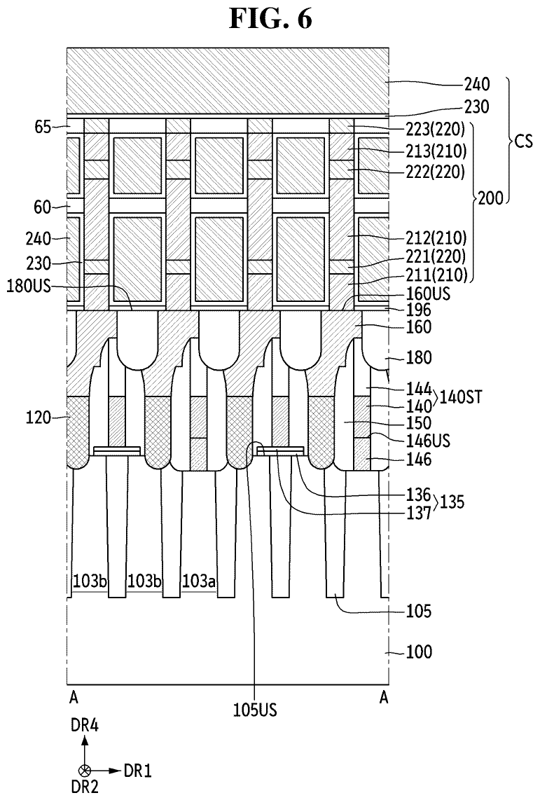

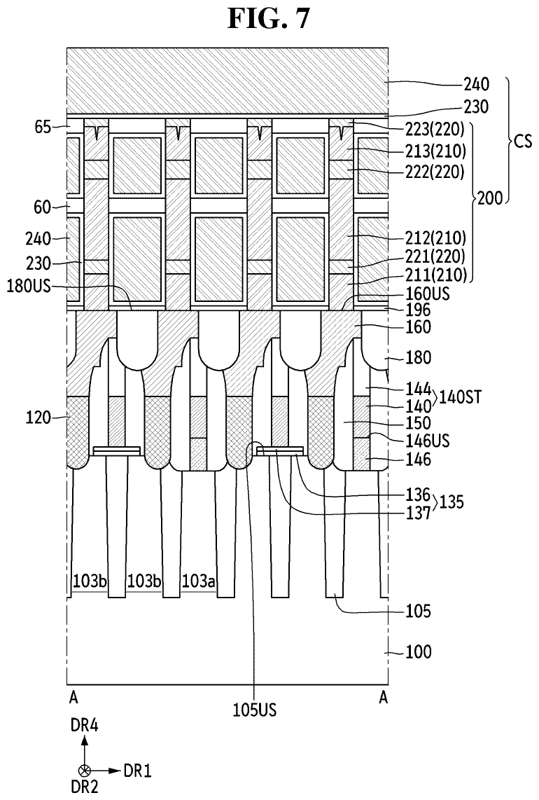

FIGS. 6 and 7 are diagrams for explaining a semiconductor device according to some example embodiments. For convenience of explanation, differences from the contents explained using FIGS. 1 to 5 will be mainly explained.

Referring to FIGS. 6 and 7, in the semiconductor device according to some example embodiments, the supporter pattern 65 disposed at the top may be disposed on the insertion film 220 disposed at the top. The supporter pattern 65 disposed at the top may be in contact with the insertion film 220 disposed at the top. The supporter pattern 65 disposed at the top may overlap the insertion film 220 disposed at the top in a direction (e.g., the first direction DR1 to the third direction DR3) aligned with the upper side of the substrate 100.

For example, the insertion film 220 may further include a third insertion film 223 on the third electrode film 213. The second supporter pattern 65 may be disposed on a side wall of the third insertion film 223. The second supporter pattern 65 may overlap the third insertion film 223 in the first direction DR1 to the third direction DR3. The second supporter pattern 65 may be in contact with the third insertion film 223. The second supporter pattern 65 may be in contact with the side wall of the third insertion film 223.

Referring to FIG. 6, the thickness of the second supporter pattern 65 in the fourth direction DR4 may be the same as the thickness of the third insertion film 223.

Referring to FIG. 7, the thickness of the second supporter pattern 65 may be different from the thickness of the third insertion film 223 in the fourth direction DR4. For example, the thickness of the second supporter pattern 65 may be thicker than the thickness of the third insertion film 223 in the fourth direction DR4, and the second supporter pattern 65 may be in contact with a part of the third insertion film 223 and the third electrode film 213. For example, the thickness of the third insertion film 223 may be thicker than the thickness of the second supporter pattern 65 in the fourth direction DR4, and the third insertion film 223 may be in contact with the second supporter pattern 65 and the capacitor dielectric film 230 thereunder. The second supporter pattern 65 may overlap a part of the third insertion film 223 and the third electrode film 213 in a direction aligned with the upper side of the substrate (for example, the first to third directions DR1, DR2, and DR3).

A part of the third insertion film 223 may penetrate (e.g., protrude) into the third electrode film 213. The third insertion film 223 may include a portion extending along the upper side of the third electrode film 213, and a portion extending into the third electrode film 213. The third insertion film 223 may be spaced apart from the second insertion film 222.

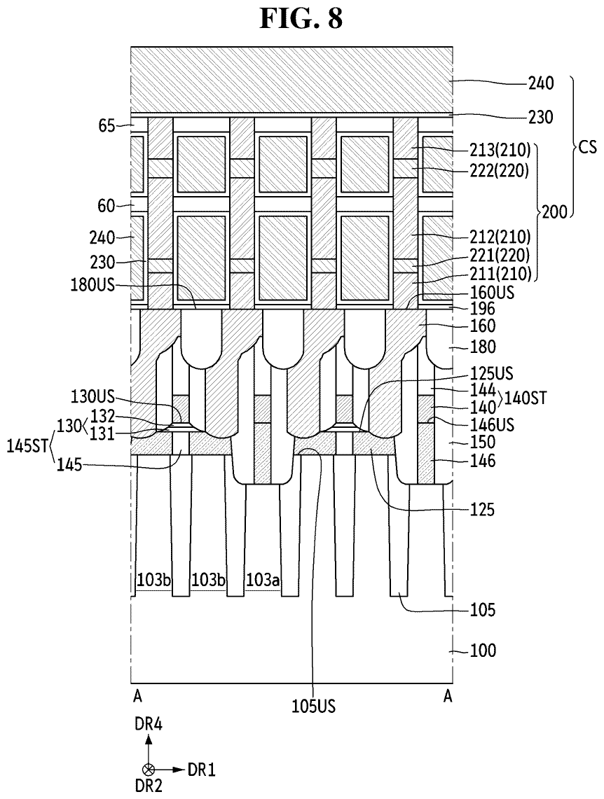

FIG. 8 is a diagram for explaining a semiconductor device according to some example embodiments. For convenience of explanation, differences from the contents explained using FIGS. 1 to 7 will be mainly explained.

Referring to FIG. 8, in the semiconductor device according to some example embodiments, a node connecting pad 125 may be disposed at the position of the storage contact 120.

The node connecting pad 125 may be disposed on the substrate 100. The node connecting pad 125 may be disposed on the storage connecting region 103b of the cell active region ACT. The node connecting pad 125 is connected to the storage connecting region 103b.

On the basis of the upper side 105US of the cell element isolation film, the upper side 125US of the node connecting pad may be lower than the upper side 146US of the bit line contact. On the basis of the upper side 105US of the cell element isolation film, the upper side 125US of the node connecting pad may be lower than the bottom side of the cell conductive line 140.

The node connecting pad 125 may electrically connect the capacitor structure CS to the substrate 100. Here, the node connecting pad 125 may correspond to a node pad XP of FIG. 1.

The node connecting pad 125 may include, for example, at least one of an impurity-doped semiconductor material, a conductive metal silicide, a conductive metal nitride, a conductive metal oxide, or a metal.

A pad isolation structure 145ST may separate the node connecting pads 125 adjacent to each other in the first direction DR1. Although not shown, the pad isolation structure 145ST may separate the node connecting pads 125 adjacent to each other in the second direction DR2. The pad isolation structure 145ST may cover the upper side 125US of the node connecting pad.

The pad isolation structure 145ST may include a pad isolation pattern 145 and an upper cell insulating film 130. The upper cell insulating film 130 may be disposed on the pad isolation pattern 145.

When the node connecting pad 125 includes a first node connecting pad and a second node connecting pad that are spaced apart from each other in the first direction DR1, the pad isolation pattern 145 may separate the first node connecting pad and the second node connecting pad in the first direction DR1. Although not shown, the pad isolation pattern 145 may also separate the node connecting pads 125 adjacent to each other in the second direction DR2.

The upper cell insulating film 130 may cover the upper side 125US of the node connecting pad. When the node connecting pad 125 includes a first node connecting pad and a second node connecting pad that are spaced apart from each other in the first direction DR1, the upper cell insulating film 130 may cover the upper side of the first node connecting pad and the upper side of the second node connecting pad.

The upper side 130US of the upper cell insulating film may be placed in the same plane as the upper side 146US of the bit line contact. The height of the upper side 130US of the upper cell insulating film may be the same as the height of the upper side 146US of the bit line contact, on the basis of the upper side 105US of the cell element isolation film.

The cell conductive line 140 may be disposed on the upper side of the pad isolation structure 145ST. The cell conductive line 140 may be disposed on the upper side 130US of the upper cell insulating film. The upper side of the pad isolation structure 145ST may be the upper side 130US of the upper cell insulating film. The upper side of the pad isolation structure 145ST may be disposed in the same plane as the bottom side of the cell conductive line 140. Although not shown, the pad isolation pattern 145 and the upper cell insulating film 130 may be disposed between the bit line contacts 146 adjacent in the second direction DR2.

The pad isolation pattern 145 may include, for example, silicon nitride, silicon oxynitride, silicon oxide, silicon carbonitride, silicon oxycarbonitride or combinations thereof. Although the upper cell insulating film 130 may be a single film, the upper cell insulating film 130 may be a multi-layer film that includes a first upper cell insulating film 131 and a second upper cell insulating film 132, as shown. For example, the first upper cell insulating film 131 may include a silicon oxide film, and the second upper cell insulating film 132 may include a silicon nitride film, but is not limited thereto. Although the width of the upper cell insulating film 130 in the first direction DR1 is shown to decrease as it goes away from the substrate 100, some example embodiments are not limited thereto.

The storage pad 160 may be disposed on each node connecting pad 125. The storage pad 160 may be electrically connected to the node connecting pad 125.

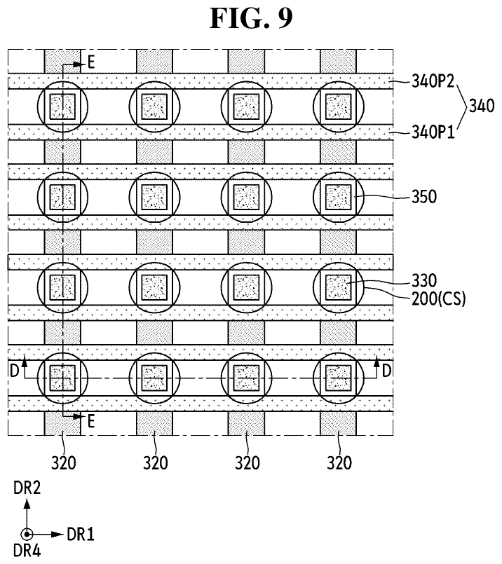

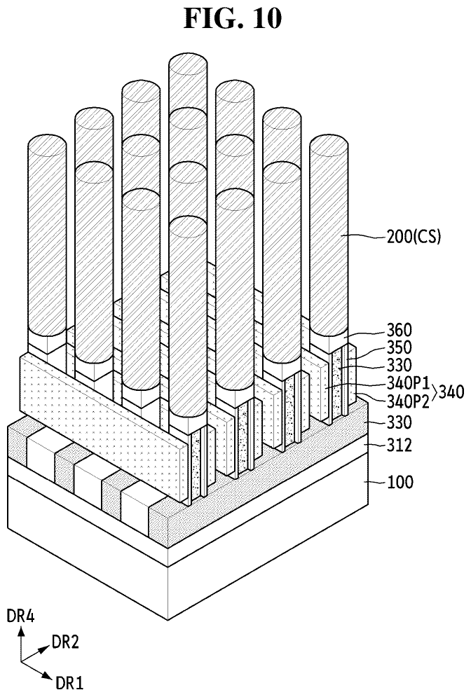

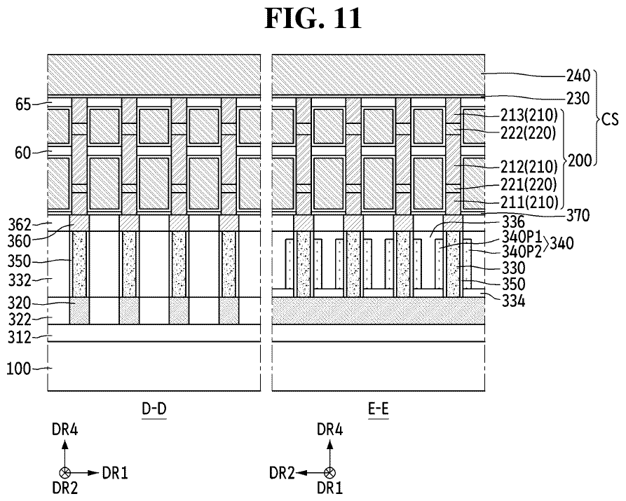

FIG. 9 is a layout diagram for explaining a semiconductor device according to some example embodiments. FIG. 10 is a perspective view for explaining the semiconductor device of FIG. 9. FIG. 11 is a cross-sectional view taken along lines D-D and E-E of FIG. 9.

Referring to FIGS. 9 to 11, the semiconductor device according to some example embodiments may include a substrate 100, a plurality of first conductive lines 320, a channel layer 330, a gate electrode 340, a gate insulating film 350, and a capacitor structure CS.

The semiconductor device according to some example embodiments may be a memory device including a vertical channel transistor VCT. The vertical channel transistor may refer to a structure in which a channel length of the channel layer 330 extends along a vertical direction (fourth direction DR4) from the substrate 100.

A first lower insulating film 312 may be disposed on the substrate 100. A plurality of first conductive lines 320 may be spaced apart from each other on the first lower insulating film 312 in the first direction DR1 and extend in the second direction DR2. A plurality of first insulating patterns 322 may be disposed on the first lower insulating film 312 to fill spaces between the plurality of first conductive lines 320. The plurality of first insulating patterns 322 may extend in the second direction DR2. The upper sides of the plurality of first insulating patterns 322 may be disposed at the same level as the upper sides of the first conductive lines 320. The plurality of first conductive lines 320 may function as bit lines BL.

The plurality of first conductive lines 320 may include a doped semiconductor material, a metal, a conductive metal nitride, a conductive metal silicide, a conductive metal oxide, or combinations thereof. For example, the plurality of first conductive lines 320 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO or combinations thereof. The plurality of first conductive lines 320 may include a single layer or plurality of layers of the above-mentioned materials. In some example embodiments, the plurality of first conductive lines 320 may include graphene, carbon nanotubes, or a combination thereof.

The channel layers 330 may be arranged in the form of a matrix in which they are disposed apart from each other in the first direction DR1 and the second direction DR2 on the plurality of first conductive lines 320. The channel layer 330 may have a first width along the first direction DR1 and a first height along the fourth direction DR4, and the first height may be greater than the first width. Here, the fourth direction DR4 maybe, for example, a direction perpendicular to the upper side of the substrate 100. For example, the first height may be, but is not limited to, about 2 to 10 times the first width. Although not shown, the bottom portion of the channel layer 330 may function as a first source/drain region, the upper portion of the channel layer 330 may function as a second source/drain region, and a portion of the channel layer 330 between the first and second source/drain regions may function as a channel region.

As an example, the channel layer 330 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 330 may include a single layer or multi-layers of the aforementioned oxide semiconductor. In some example embodiments, the channel layer 330 may have a bandgap energy greater than the bandgap energy of silicon. For example, the channel layer 330 may have a bandgap energy of about 1.5 eV to 5.6 eV. For example, the channel layer 330 may have optimum channel performance when having the bandgap energy of about 2.0 eV to 4.0 eV. For example, the channel layer 330 may be, but is not limited to, polycrystalline or amorphous. As another example, the channel layer 330 may include graphene, carbon nanotube or a combination thereof. As yet another example, the channel layer 330 may include a silicon-based semiconductor material. The channel layer 330 may include a single crystal semiconductor material, and may include, for example, but is not limited to, single crystal silicon or single crystal silicon-germanium

A gate electrode 340 may extend in the first direction DR1 on both side walls of the channel layer 330. The gate electrode 340 may include a first sub-gate electrode 340P1 that faces a first side wall of the channel layer 330, and a second sub-gate electrode 340P2 that faces a second side wall opposite to the first side wall of the channel layer 330. As the single channel layer 330 is disposed between the first sub-gate electrode 340P1 and the second sub-gate electrode 340P2, the semiconductor device may have a dual gate transistor structure. However, some example embodiments of the present disclosure are not limited thereto, and the second sub-gate electrode 340P2 may be omitted, and only the first sub-gate electrode 340P1 that faces the first side wall of the channel layer 330 may be formed to realize a single gate transistor structure. The gate electrode 340 may function as a word line WL of the memory cell. The materials included in the gate electrode 340 may be the same as description of the cell gate electrode 112.

A gate insulating film 350 surrounds side walls of the channel layer 330, and may be interposed between the channel layer 330 and the gate electrode 340. For example, as shown in FIG. 9, the entire side wall of the channel layer 330 may be surrounded by the gate insulating film 350, and a part of the side wall of the gate electrode 340 may be in contact with the gate insulating film 350. In some other example embodiments, the gate insulating film 350 extends in an extending direction (e.g., the first direction DR1) of the gate electrode 340, and only the two side walls that face the gate electrode 340 among the side walls of the channel layer 330 may be in contact with the gate insulating film 350. In some example embodiments, the gate insulating film 350 may be made up of a silicon oxide, a silicon oxynitride, a high dielectric constant material having a higher dielectric constant than the silicon oxide or a combination thereof.

A plurality of second insulating patterns 332 may extend along the second direction DR2 on the plurality of first insulating patterns 322. The channel layer 330 may be disposed between two adjacent second insulating patterns 332 among the plurality of second insulating patterns 332. Further, a first buried layer 334 and a second buried layer 336 may be disposed in a space between two adjacent channel layers 330, between two adjacent second insulating patterns 332. The first buried layer 334 may be disposed at the bottom portion of the space between two adjacent channel layers 330. The second buried layer 336 may be formed to fill the remainder of the space between two adjacent channel layers 330 on the first buried layer 334. The upper side of the second buried layer 336 may be disposed at the same level as the upper side of the channel layer 330, and the second buried layer 336 may cover the upper side of the gate electrode 340. In contrast, the plurality of second insulating patterns 332 may be formed of a continuous material layer with the plurality of first insulating patterns 322, or the second buried layer 336 may be formed of a continuous material layer with the first buried layer 334.

Capacitor contacts 360 may be disposed on the channel layer 330. The capacitor contacts 360 are disposed to vertically overlap the channel layer 330, and may be arranged in the form of a matrix in which they are spaced apart from each other in the first direction DR1 and the second direction DR2. The capacitor contacts 360 may be made up of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO or a combination thereof.

An upper insulating film 362 may surround the side walls of the capacitor contacts 360 on the plurality of second insulating patterns 332 and the second buried layer 336. The second etch stop layer 370 may be disposed on the upper insulating film 362. The capacitor structure CS may be disposed on the second etch stop layer 370.

The capacitor structure CS may include a lower electrode 200, a capacitor dielectric film 230, and an upper electrode 240. The lower electrode 200 penetrates the second etch stop layer 370, and may be electrically connected to the upper side of the capacitor contact 360. The lower electrode 200 may be formed, but is not limited to, in a pillar shape extending in the fourth direction DR4. In some example embodiments, the lower electrodes 200 are disposed to vertically overlap the capacitor contacts 360, and may be disposed in the form of a matrix in which they are spaced apart from each other in the first direction DR1 and the second direction DR2. In contrast, a landing pad (not shown) is further disposed between the capacitor contact 360 and the lower electrode 200, and the lower electrode 200 may be arranged in a hexagonal shape.

At least one or more supporter patterns 60 and 65 may be disposed on the second etch stop layer 370. Unlike the shown example, the semiconductor device according to some example embodiments may not include at least one or more supporter patterns 60 and 65 that support the side wall of the lower electrode 200.

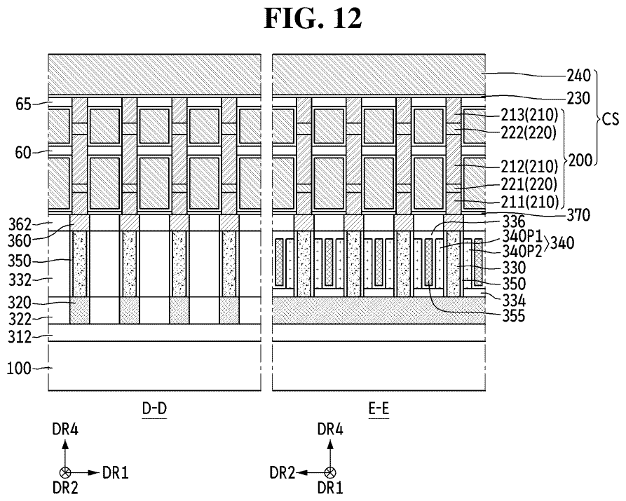

FIG. 12 is a diagram for explaining a semiconductor device according to some example embodiments. For convenience of explanation, differences from the contents using FIGS. 9 to 11 will be mainly explained.

Referring to FIG. 12, the semiconductor device according to some example embodiments may further include a back gate electrode 355.

The back gate electrode 355 may be disposed between the channel layers 330 adjacent to each other in the second direction DR2. For example, the back gate electrode 355 may be disposed inside the second buried layer 336.

A voltage may be applied to the back gate electrode 355 to adjust the threshold voltage of the vertical channel transistor. The threshold voltage of the vertical channel transistor may be adjusted to limit and/or prevent the leakage current characteristics from deteriorating.

The back gate electrode 355 includes a conductive material, and may include, for example, at least one of a conductive semiconductor material, a conductive metal nitride, a conductive metal silicon nitride, a metal carbonitride, a conductive metal silicide, a conductive metal oxide, a two-dimensional material, and a metal.

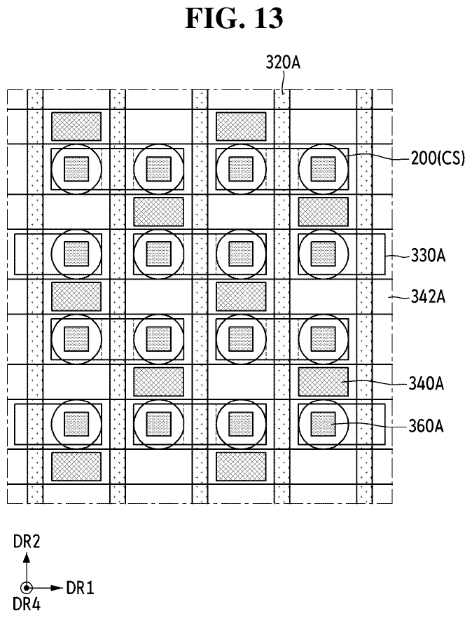

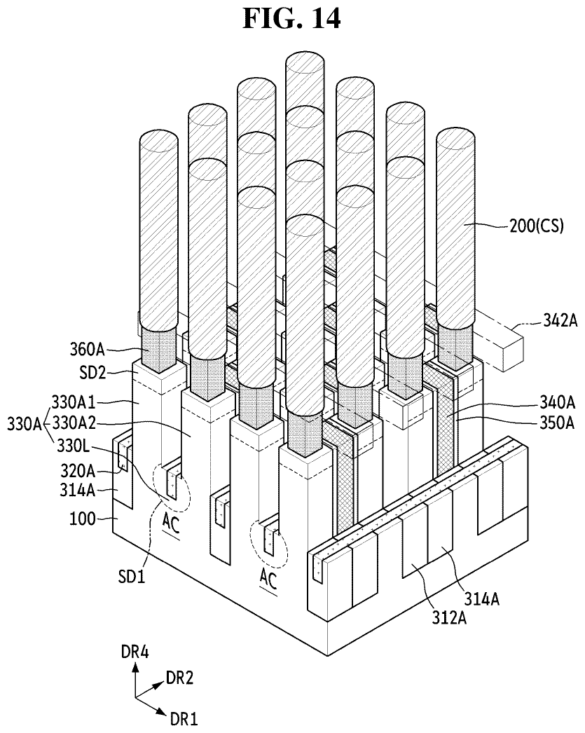

FIG. 13 is a layout diagram for explaining a semiconductor device according to some example embodiments. FIG. 14 is a perspective view for explaining the semiconductor device of FIG. 13.

Referring to FIGS. 13 and 14, the semiconductor device according to some example embodiments may include a substrate 100, a plurality of first conductive lines 320A, a channel structure 330A, a contact gate electrode 340A, a plurality of second conductive lines 342A, and a capacitor structure CS. The semiconductor device according to some example embodiments may be a memory device including a vertical channel transistor VCT.

A plurality of active regions AC may be defined by the first element isolation pattern 312A and the second element isolation pattern 314A on the substrate 100. The channel structure 330A may be disposed in each active region AC. The channel structure 330A may include a first active pillar 330A1 and a second active pillar 330A2 that each extend in the vertical direction, and a connecting portion 330L connected to a bottom portion of the first active pillar 330A1 and a bottom portion of the second active pillar 330A2. A third source/drain region SD1 may be disposed inside the connecting portion 330L. A fourth source/drain region SD2 may be disposed above the first and second active pillars 330A1 and 330A2. Each of the first active pillar 330A1 and the second active pillar 330A2 may form an independent unit memory cell.

The plurality of first conductive lines 320A may extend in a direction intersecting each of the plurality of active regions AC, and may extend, for example, in the second direction DR2. One first conductive line 320A among the plurality of first conductive lines 320A may be disposed on the connecting portion 330L between the first active pillar 330A1 and the second active pillar 330A2. One first conductive line 320A may be disposed on the third source/drain region SD1. The other first conductive line 320A adjacent to the one first conductive line 320A may be disposed between the two channel structures 330A. One first conductive line 320A among the plurality of first conductive lines 320A may function as a common bit line included in the two unit memory cells constituted by the first active pillar 330A1 and the second active pillar 330A2 disposed on both sides of the one first conductive line 320A.

One contact gate electrode 340A may be disposed between the two channel structures 330A adjacent to each other in the second direction DR2. For example, the contact gate electrode 340A may be disposed between the first active pillar 330A1 included in one channel structure 330A and the second active pillar 330A2 of the channel structure 330A adjacent thereto. One contact gate electrode 340A may be shared by the first active pillar 330A1 and the second active pillar 330A2 disposed on both side walls thereof. A fourth gate insulating film 350A may be disposed between the contact gate electrode 340A and the first active pillar 330A1, and between the contact gate electrode 340A and the second active pillar 330A2. The plurality of second conductive lines 342A may extend in the first direction DR1 on the upper side of the contact gate electrode 340A. The plurality of second conductive lines 342A may function as word lines of the memory cell.

A capacitor contact 360A may be disposed on the channel structure 330A. The capacitor contact 360A may be disposed on the fourth source/drain region SD2, and the capacitor structure CS may be disposed on the capacitor contact 360A.

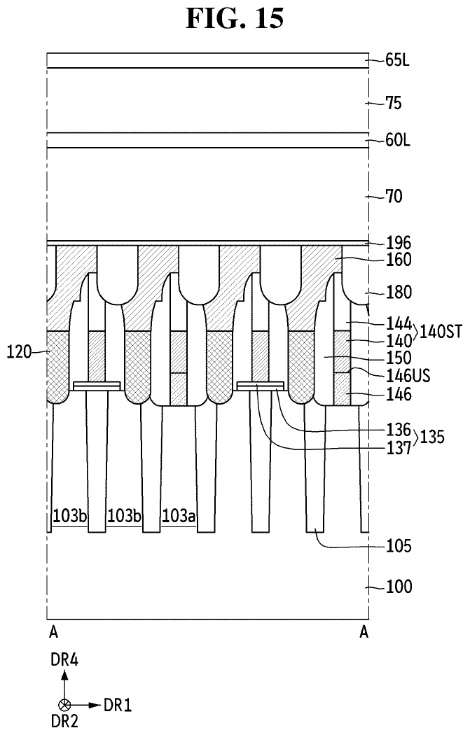

FIGS. 15 to 22 are intermediate stage diagrams for explaining a method for fabricating a semiconductor device according to some example embodiments. For convenience of description, repeated parts of those explained using FIGS. 1 to 8 will be briefly explained or omitted.

Referring to FIG. 15, a plurality of bit line structures 140ST, a plurality of storage contacts 120, a plurality of bit line contacts 146, and a plurality of storage pads 160 may be formed on the substrate 100.

The first etch stop layer 196 may be formed on the storage pad 160 and the pad isolation insulating film 180.

The first mold layer 70, the first supporter film 60L, the second mold layer 75, and the second supporter film 65L may be sequentially formed on the first etch stop layer 196. Each of the first mold layer 70 and the second mold layer 75 may include, but are not limited to, silicon oxide. The first supporter film 60L and the second supporter film 65L may include an insulating material having an etching selectivity with respect to the first mold layer 70 and the second mold layer 75.

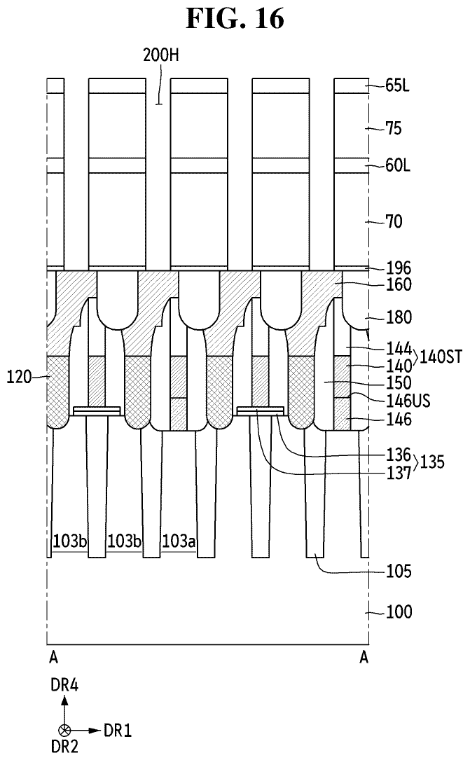

Referring to FIG. 16, a plurality of lower electrode holes 200H may be formed inside the first mold layer 70, the first supporter film 60L, the second mold layer 75, and the second supporter film 65L.

Each lower electrode hole 200H may penetrate the first mold layer 70, the first supporter film 60L, the second mold layer 75, and the second supporter film 65L. Each lower electrode hole 200H may penetrate the first etch stop layer 196 to expose the storage pad 160.

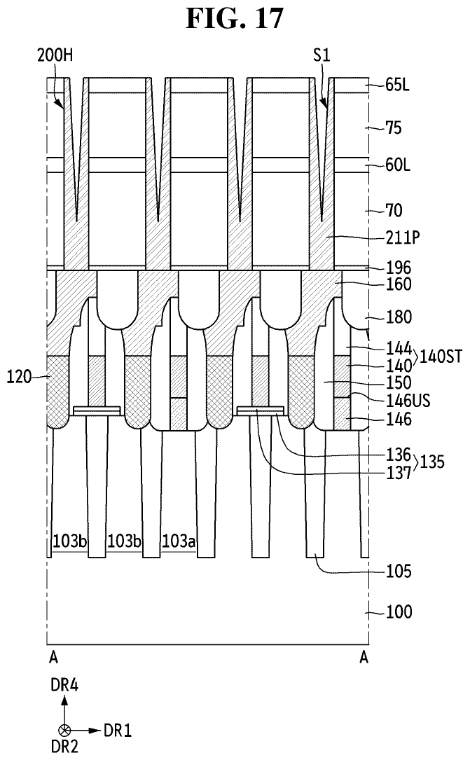

Referring to FIG. 17, a first preliminary electrode film 211P may be formed inside the lower electrode hole 200H. The first preliminary electrode film 211P may be electrically connected to the storage pad 160. The first preliminary electrode film 211P may be formed by, for example, an ALD (Atomic Layer Deposition), a CVD (Chemical Vapor Deposition) or the like.

For example, the first preliminary electrode film 211P may include a shim S1 therein. The shim S1 in the first preliminary electrode film 211p may define a gap or space having tapered shape. The lowermost portion of the first shim S1 may be spaced apart from the storage pad 160 in the fourth direction DR4. The first preliminary electrode film 211P may fill a part of the lower electrode hole 200H. In contrast, the first preliminary electrode film 211P may not include the first shim S1 therein.

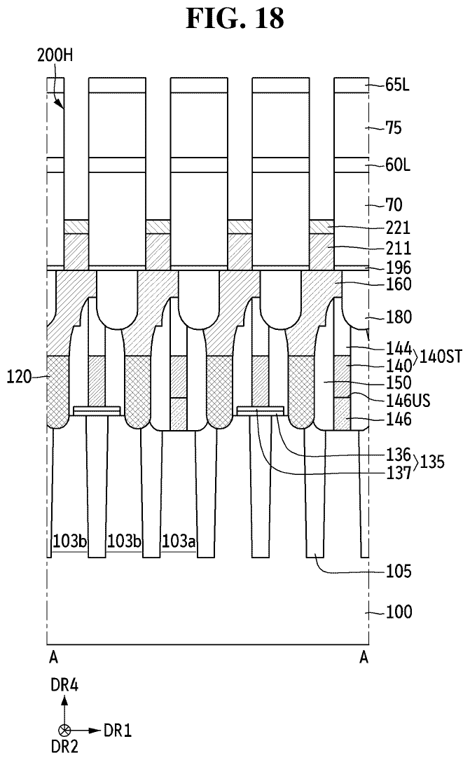

Referring to FIGS. 17 and 18, an etching process may be performed on the first preliminary electrode film 211P to form the first electrode film 211. The etching process may be an etch-back process. As a result, the first shim S1 may be removed.

A first insertion film 221 may be formed on the first electrode film 211 inside the lower electrode hole 200H. For example, a preliminary insertion film may be formed on the first electrode film 211, and then an etching process (e.g., an etch-back process or a wet etching process) may be performed on the preliminary insertion film to form the first insertion film 221. The preliminary insertion film may be formed by, for example, an ALD (Atomic Layer Deposition), a CVD (Chemical Vapor Deposition) or the like.

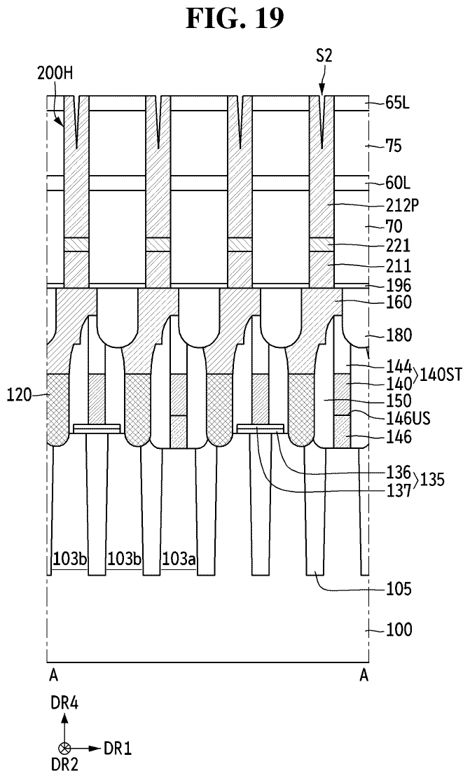

Referring to FIG. 19, a second preliminary electrode film 212P may be formed on the first insertion film 221. The second preliminary electrode film 212P may be formed by, for example, an ALD, a CVD, or the like.

For example, the second preliminary electrode film 212P may include a second shim S2 therein. The second shim S2 in second preliminary electrode film 212p may define a gap or space having tapered shape. The lowermost portion of the second shim S2 may be higher than the upper side of the first supporter film 60L. In contrast, the second preliminary electrode film 212P may not include the second shim S2 therein.

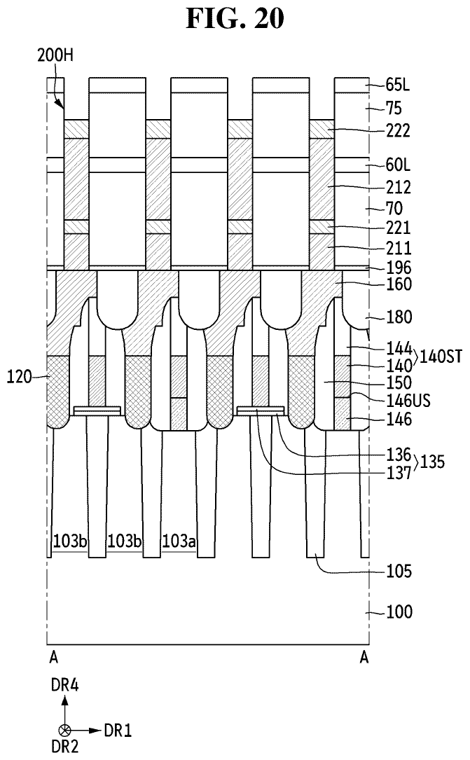

Referring to FIGS. 19 and 20, an etching process (e.g., an etch-back process) may be formed on the second preliminary electrode film 212P to form the second electrode film 212. As a result, the second shim S2 may be removed.

The second insertion film 222 may be formed on the second electrode film 212 inside the lower electrode hole 200H. For example, the preliminary insertion film is formed on the second electrode film 212, and then an etching process (e.g., an etch-back process or a wet etching process) may be performed on the preliminary insertion film to form the second insertion film 222. The preliminary insertion film may be formed by, for example, an ALD, a CVD or the like.

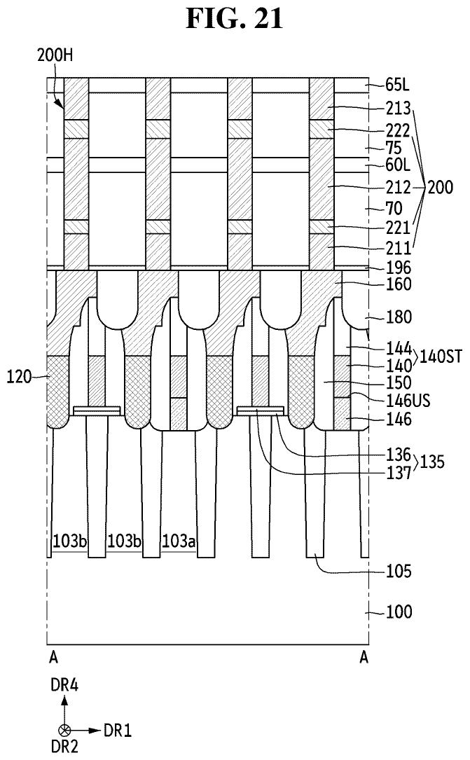

Referring to FIG. 21, the third electrode film 213 may be formed on the second insertion film 222. The third electrode film 213 may fill the lower electrode hole 200H on the second insertion film 222. As a result, the lower electrode 200 that includes the first electrode film 211, the first insertion film 221, the second electrode film 212, the second insertion film 222, and the third electrode film 213 may be formed. For example, a preliminary electrode film that fills the lower electrode hole 200H and covers the second supporter film 65L is formed on the second insertion film 222, and then an etching process (e.g., an etch-back process or a planarization process) may be performed on the preliminary insertion film to form the third electrode film 213. The preliminary electrode film may be formed by, for example, an ALD, a CVD or the like.

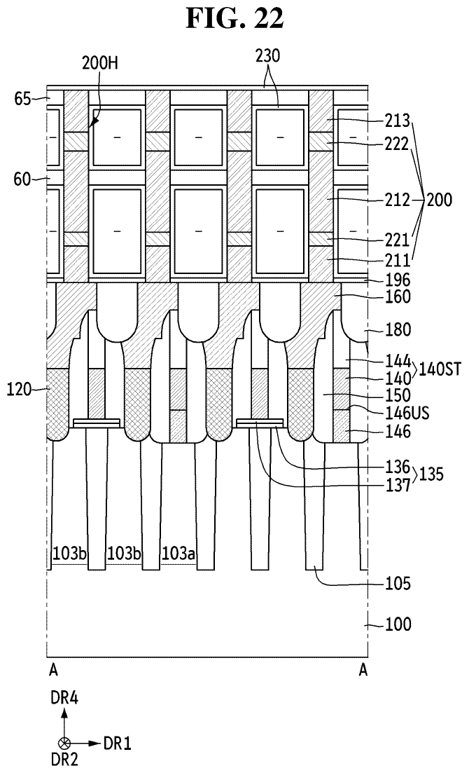

Referring to FIGS. 21 and 22, the first supporter pattern 60 and the second supporter pattern 65 may be formed by forming openings in each of the first supporter film 60L and the second supporter film 65L.

Although not shown, each of the first supporter pattern 60 and the second supporter pattern 65 may include a through hole. The first mold layer 70 and the second mold layer 75 may be removed, using the through hole of the first supporter pattern 60 and the through hole of the second supporter pattern 65.

For example, the second supporter pattern 65 may be formed by forming a through hole in the second supporter film 65L. The through hole of the second supporter pattern 65 may expose the second mold layer 75. The second mold layer 75 may be removed, using the through holes of the second supporter pattern 65. Next, by forming the through hole in the first supporter film 60L, the first supporter pattern 60 may be formed. The through hole of the first supporter pattern 60 may be formed at a position corresponding to the through hole of the second supporter pattern 65. The through hole of the first supporter pattern 60 may expose the first mold layer 70. The first mold layer 70 may be removed, using the through hole of the first supporter pattern 60.

After removing the first mold layer 70 and the second mold layer 75, a capacitor dielectric film 230 may be formed on the exposed first etch stop layer 196, the lower electrode 200, the first supporter pattern 60, and the second supporter pattern 65. The capacitor dielectric film 230 may extend along the exposed first etch stop layer 196, the lower electrode 200, the first supporter pattern 60, and the second supporter pattern 65. The capacitor dielectric film 230 may extend along the upper side of the second supporter pattern 65 and the upper side of the lower electrode 200.

Referring to FIG. 2, an upper electrode 240 may be formed on the capacitor dielectric film 230.

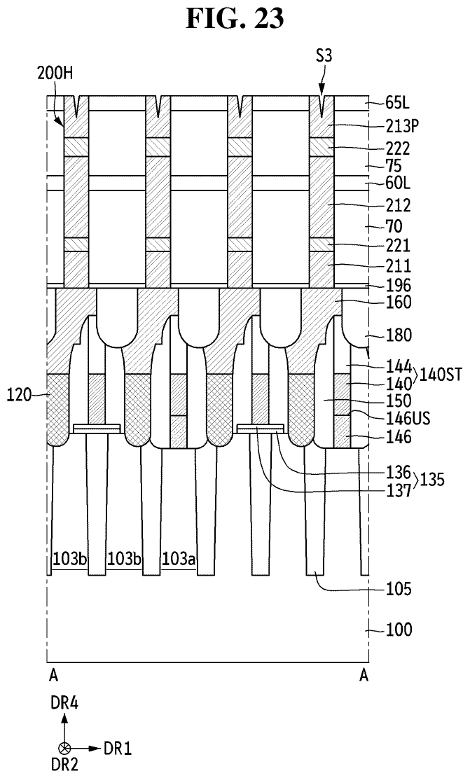

FIGS. 23 to 25 are intermediate stage diagrams for explaining a method for fabricating a semiconductor device according to some example embodiments. FIG. 23 shows a fabrication process that proceeds or occurs after the fabrication process described with respect to FIG. 20.

Referring to FIG. 23, a third preliminary electrode film 213P may be formed on the second insertion layer 222 inside the lower electrode hole 200H. For example, the third preliminary electrode film 213P may include a third shim S3 therein. The third shim S3 in third preliminary electrode film 213p may define a gap or space having tapered shape. The lowermost portion of the third shim S3 may be higher than the upper side of the second insertion film 222. In contrast, the second preliminary electrode film 212P may not include the second shim S2 therein.

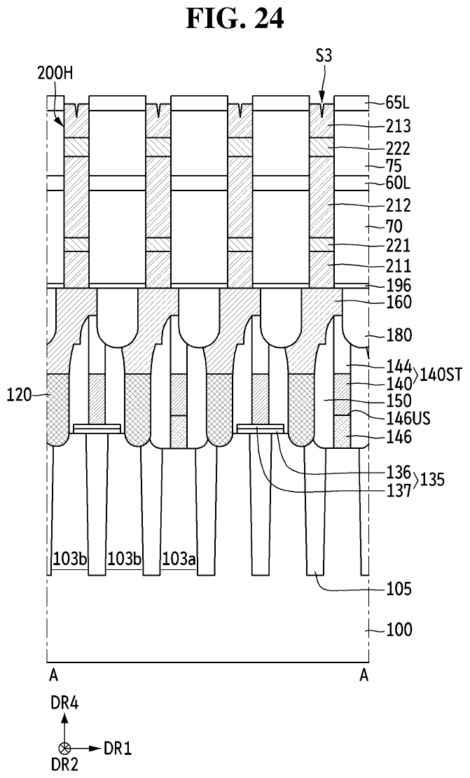

Referring to FIGS. 23 and 24, an etching process (e.g., an etch-back process) may be performed on the third preliminary electrode film 213P to form the third electrode film 213. The upper side of the third electrode film 213 may be lower than the upper side of the second supporter film 65L. The third shim S3 may remain or may be removed. When the third shim S3 is removed, the semiconductor device of FIG. 6 may be fabricated.

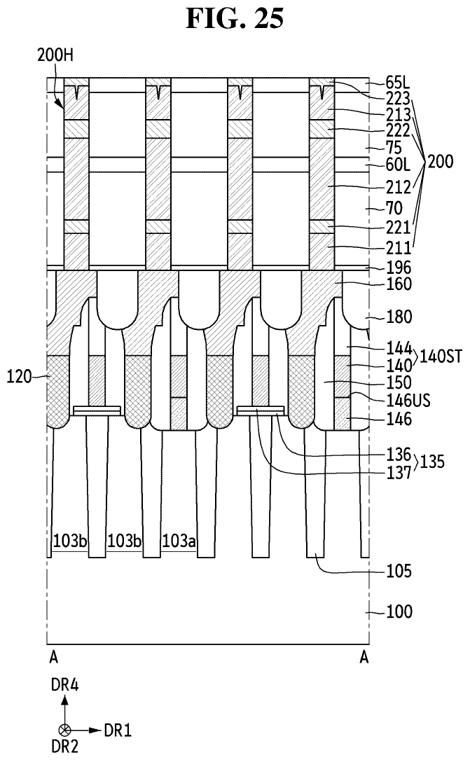

Referring to FIGS. 24 and 25, a third insertion film 223 may be formed on the third electrode film 213. The third insertion film 223 may fill the third shim S3. The third insertion film 223 may fill the lower electrode hole 200H.

Next, referring to FIG. 7, as explained with respect to FIGS. 21 to 23, openings may be formed in each of the first supporter film 60L and the second supporter film 65L to form the first supporter pattern 60 and the second supporter pattern 65. After removing the first mold layer 70 and the second mold layer 75, the capacitor dielectric film 230 and the upper electrode 240 may be formed.

Some example embodiments of the inventive concepts may further provide a method of manufacturing a semiconductor device that includes forming a lower electrode on a landing pad of a substrate, the lower electrode extending in a first direction; forming a first supporter pattern on a side wall of the lower electrode; forming a second supporter pattern on the side wall of the lower electrode, the second supporter pattern being spaced apart from the first supporter pattern in the first direction; forming a capacitor dielectric film on the lower electrode, the first supporter pattern and the second supporter pattern; and forming an upper electrode on the capacitor dielectric film. The forming the lower electrode may include forming a first electrode film on the landing pad; forming a first insertion film over the first electrode film; forming a second electrode film over the first insertion film; forming a second insertion film over the second electrode film; and forming a third electrode film over the second insertion film. The first supporter pattern may be above the first insertion film in the first direction, and the second insertion film may be between the first supporter pattern and the second supporter pattern in the first direction.

In some example embodiments of the method of manufacturing the semiconductor device, a material of the first electrode film, the second electrode film and the third electrode film includes a different material than a material of the first insertion film and the second insertion film.

In some example embodiments of the method of manufacturing the semiconductor device, the forming the second supporter pattern includes contacting the second supporter pattern with the third electrode film.

In some example embodiments of the method of manufacturing the semiconductor device, the forming of the lower electrode further includes forming a third insertion film over the third electrode film.

In some example embodiments of the method of manufacturing the semiconductor device, the forming the second supporter pattern includes forming the second supporter pattern as contacting a part of the third electrode film and a part of the third insertion film.

In some example embodiments of the method of manufacturing the semiconductor device, the forming of the third insertion film includes forming the third insertion film as penetrating into the third electrode film.
In some example embodiments of the method of manufacturing the semiconductor device, a material of the third insertion film includes a same material as a material of the first insertion film and the second insertion film.
In some example embodiments of the method of manufacturing the semiconductor device, the forming the lower electrode further includes forming a fourth electrode film on the first insertion film, and forming a third insertion film on the fourth electrode film. The third insertion film may be below the first supporter pattern and below the second electrode film.
In some example embodiments of the method of manufacturing the semiconductor device, the forming of the lower electrode further includes forming a fourth insertion film on the second electrode film, and forming a fifth electrode film on the fourth insertion film. The fourth insertion film may be between the first supporter pattern and the second supporter pattern.
Although some example embodiments of the present disclosure have been described above with reference to the accompanying drawings, the present disclosure is not limited to the above some example embodiments and may be fabricated in various different forms. Those skilled in the art will appreciate that the present disclosure may be embodied in other specific forms without changing the technical spirit or essential features of the inventive concepts. Accordingly, the above-described some example embodiments should be understood in all respects as illustrative and not restrictive.

What is claimed is:

1. A semiconductor device comprising:
a lower electrode extending in a first direction, the lower electrode including an electrode film and an insertion film, the electrode film and the insertion film including different materials from each other;
a first supporter pattern on a side wall of the lower electrode;
a second supporter pattern on the side wall of the lower electrode, the second supporter pattern being spaced apart from the first supporter pattern in the first direction;
a capacitor dielectric film on the lower electrode, the first supporter pattern, and the second supporter pattern; and
an upper electrode on the capacitor dielectric film,
wherein
the electrode film includes a first electrode film, a second electrode film on the first electrode film, and a third electrode film on the second electrode film,
the insertion film includes a first insertion film and a second insertion film, the first insertion film between the first electrode film and the second electrode film, and the second insertion film between the second electrode film and the third electrode film,
the first insertion film is below the first supporter pattern in the first direction, and
the second insertion film is between the first supporter pattern and the second supporter pattern in the first direction.

2. The semiconductor device of claim 1, wherein
the second supporter pattern is in contact with the third electrode film.

3. The semiconductor device of claim 1, wherein
the insertion film further includes a third insertion film on the third electrode film, and
the second supporter pattern is in contact with the third insertion film.

4. The semiconductor device of claim 1, wherein
the insertion film further includes a third insertion film on the third electrode film, and
the second supporter pattern is in contact with a part of the third electrode film and a part of the third insertion film.

5. The semiconductor device of claim 4, wherein
the part of the third insertion film penetrates into the third electrode film.

6. The semiconductor device of claim 1, wherein
a material of the first insertion film includes a different material than a material of the second insertion film.

7. The semiconductor device of claim 1, wherein
a material of the first insertion film includes a same material as a material of the second insertion film.

8. The semiconductor device of claim 1, wherein
a thickness of the first insertion film in the first direction is different than a thickness of the second insertion film in the first direction.

9. The semiconductor device of claim 1, wherein
the insertion film further includes a third insertion film,
the electrode film further includes a fourth electrode film on the third insertion film, and
the third insertion film and the fourth electrode film are at least one of
between the first electrode film and the first insertion film, and
between the second insertion film and the third electrode film.

10. The semiconductor device of claim 9, wherein
a material of the third insertion film includes a same material as a material of the first insertion film and a material of the second insertion film.

11. The semiconductor device of claim 9, wherein
a material of the third insertion film includes a material different than at least one of a material of the first insertion film and a material of the second insertion film.

12. The semiconductor device of claim 9, wherein
a thickness of the third insertion film in the first direction is different than at least one of a thickness of the first insertion film in the first direction and a thickness of the second insertion film in the first direction.

13. A semiconductor device comprising:
a lower electrode extending in a first direction, the lower electrode including a first electrode film, a second electrode film spaced apart from the first electrode film in the first direction, and a first insertion film between the first electrode film and the second electrode film;
a first supporter pattern on one of a side wall of the first electrode film and a side wall of the second electrode film;
a capacitor dielectric film on the lower electrode and the first supporter pattern; and
an upper electrode on the capacitor dielectric film,
wherein a material of the first insertion film includes a material different than a material of the first electrode film and a material of the second electrode film.

14. The semiconductor device of claim 13, further comprising:
a second supporter pattern on the side wall of the second electrode film,
wherein the first supporter pattern is on the side wall of the first electrode film.

15. The semiconductor device of claim 13, further comprising:
a third electrode film between the first electrode film and the first insertion film, and a second insertion film between the third electrode film and the first insertion film,
wherein a material of the second insertion film includes a material different than the material of the first electrode film, the material of the second electrode film, and a material of the third electrode film.

16. The semiconductor device of claim 15, wherein
the material of the first insertion film includes a material different than the material of the second insertion film.

17. The semiconductor device of claim 15, wherein
a thickness of the first insertion film in the first direction is different than a thickness of the second insertion film in the first direction.

18. A semiconductor device comprising:
a substrate including an active region defined by an element isolation film, the active region extending in a first direction, and the active region including a first portion and a second portion defined on both sides of the first portion;
a word line extending in a second direction different than the first direction, the word line extending in the substrate and the element isolation film, and the word line crossing between the first portion of the active region and the second portion of the active region;
a bit line contact electrically connected to the first portion of the active region;
a bit line on the bit line contact, the bit line being electrically connected to the bit line contact, and the bit line extending in a third direction different than the first direction and the second direction;
a landing pad electrically connected to the second portion of the active region;
a capacitor structure electrically connected to the landing pad; and
a first supporter pattern on the capacitor structure,
wherein the capacitor structure includes
a lower electrode electrically connected to the landing pad, the lower electrode extending in a fourth direction,
a capacitor dielectric film on the lower electrode and the first supporter pattern, and
an upper electrode on the capacitor dielectric film, and
wherein
the lower electrode includes a first electrode film, a first insertion film, and a second electrode film stacked in sequence in the fourth direction, and
the first supporter pattern overlaps one of the first electrode film and the second electrode film in the first direction, the second direction and the third direction, and does not overlap the first insertion film in the first direction, the second direction and the third direction.

19. The semiconductor device of claim 18, wherein
a material of the first insertion film includes a material different than a material of the first electrode film and a material of the second electrode film.

20. The semiconductor device of claim 18, wherein
the lower electrode further comprises a second insertion film and a third electrode film stacked in sequence in the fourth direction on the second electrode film, and
a material of the second insertion film includes a material different than a material of the first electrode film, a material of the second electrode film, and a material of the third electrode film.
